(19) United States
(12) Patent Application Publication
(10) Pub. No.: US 2025/0008848 A1
(43) Pub. Date: Jan. 2, 2025

(54) LOW DRIFT PHASE CHANGE MATERIAL COMPOSITE MATRIX

(71) Applicant: International Business Machines Corporation, Armonk, NY (US)

(72) Inventors: Kevin W. Brew, Niskayuna, NY (US); Timothy Mathew Philip, Albany, NY (US); Jin Ping Han, Yorktown Heights, NY (US); Ching-Tzu Chen, Ossining, NY (US)

(21) Appl. No.: 18/344,194

(22) Filed: Jun. 29, 2023

(51) Int. Cl. H10N 70/00; C09K 5/06; H10B 63/10; H10N 70/20

(52) U.S. Cl. CPC H10N 70/828; C09K 5/063; H10B 63/10; H10N 70/026; H10N 70/231; H10N 70/881

(57) ABSTRACT

A phase change memory device that includes a composite phase change material layer comprising a mixture of a dispersed phase of a projection material of a first resistivity, and a matrix of a phase-change material of a second resistivity or third resistivity dependent on phase. The first resistivity of the projection material has a resistance that is greater than the second resistance for the phase change material, and is less than the third resistance of the phase change material. The phase change memory device further includes a first electrode; and a second electrode on opposing faces of the composite phase change material layer. The projection material forms a percolated conducting path from the first electrode to the second electrode.

### BACKGROUND

The present invention generally relates to phase change materials, and more particularly to phase change memory having low drift characteristics.

Phase-change memory (PCM) is a non-volatile solid-state memory technology that exploits the reversible, thermally-assisted switching of phase-change materials, in particular chalcogenide compounds such as GST (Germanium-Antimony-Tellurium), between states with different electrical resistance. The fundamental storage unit (the “cell”) can be programmed into a number of different states, or levels, which exhibit different resistance characteristics. The s programmable cell-states can be used to represent different data values, permitting storage of information.

In single-level PCM devices, each cell can be set to one of s=2 states, a “SET” state and a “RESET” state, permitting storage of one bit per cell. In the RESET state, which corresponds to an amorphous state of the phase-change material, the electrical resistance of the cell is very high. By heating to a temperature above its crystallization point and then cooling, the phase-change material can be transformed into a low-resistance, crystalline state. This low-resistance state provides the SET state of the cell. If the cell is then heated to a high temperature, above the melting point of the phase-change material, the material reverts to the fully-amorphous RESET state on rapid cooling. In multilevel PCM devices, the cell can be set to s>2 programmable states permitting storage of more than one bit per cell. The different programmable states correspond to different relative proportions of the amorphous and crystalline phases within the volume of phase-change material. In particular, in addition to the two states used for single-level operation, multilevel cells exploit intermediate states in which the cell contains different volumes of the amorphous phase within the otherwise crystalline PCM material. Since the two material phases exhibit a large resistance contrast, varying the size of the amorphous phase within the overall cell volume produces a corresponding variation in cell resistance.

Reading and writing of data in PCM cells is achieved by applying appropriate voltages to the phase-change material via a pair of electrodes associated with each cell. In a write operation, the resulting programming signal causes Joule heating of the phase-change material to an appropriate temperature to induce the desired cell-state on cooling. Reading of PCM cells is performed using cell resistance as a metric for cell-state. An applied read voltage causes a current to flow through the cell, this read current being dependent on resistance of the cell. Measurement of the cell read current therefore provides an indication of the programmed cell state. A sufficiently low read voltage is used for this resistance metric to ensure that application of the read voltage does not disturb the programmed cell state. Cell state detection can then be performed by comparing the resistance metric with predefined reference levels for the s programmable cell-states.

Phase change memory (PCM) have been considered to be a fundamental device for a low power interface towards enterprise artificial intelligence (AI). However, phase-change memory (PCM) devices face challenges for overcoming resistance drift, an issue where PCM cell resistance increases as a function of time. Unit cells of PCM often comprise multiple memristive devices, e.g., 6T4R, to improve accuracy of the written weight value. The resistance of each phase change memory PCM) cell can drifts over time leading to higher and higher resistance. This can result in creating volatility in the weight corresponding to the assigned data stored in the phase change memory (PCM), which can require additional hardware and/or software to correct. Several solutions have been proposed to resolve the impact of drift in phase change memory (PCM) devices. Some of the proposed solutions include projection liner phase change memory (PCM), phase change heterostructures (PCH), and interfacial phase change memory (iPCM).

Projection liner phase change memory (PCM) is difficult to apply the appropriate material compositions that will be compatible with functional phase change memory (PCM) integration. Further, it has been determined that phase change heterostructures (PCH), and interfacial phase change memory (iPCM) are difficult to deposit and require precise temperature control. Additionally, the application of phase change heterostructures (PCH) to memory applications, and interfacial phase change memory (iPCM) have faced significant difficulty for failing to provide quality epitaxial grown for Van der Waals gap formation. This has often rendered phase change heterostructures (PCH) in memory applications and interfacial phase change memory (iPCM) non-manufacturable. Solubility of the layers in iPCM also preclude high endurance as they eventually react to form high drift PCM.

### SUMMARY

In some embodiments, the methods and structures described herein can overcome the aforementioned difficulty by forming a lower drift phase change memory (PCM) composite matrix. The phase change material of the present disclosure can be formed using sputtering. By employing co-sputtering, a marginally conductive material (˜˜10× Res that of the crystalline PCM) may be mixed with phase change material (e.g. GST) in the phase change material layer in the phase change memory (PCM) element to form a projection matrix composite. For example, the phase change materials may be Ge₂Sb₂Te₅. Dielectric additives, such as Al₂O₃, Si₃N₄, SiO₂, SiO, TiO₂, HfO₂, etc., may be used in PCM materials as a non-conductive additive in amounts as great as 50 at %. However, the methods and structures of the present disclosure can substitute these non-conductive additives with a marginally conducting non-drifting material, such as a metal nitride, metal oxide, doped semiconductor, small bandgap semiconductor, semi-metals, topological insulator, topological semimetal, Van der Waal material or combination thereof. The marginally conductive non-drifting material may be referred to as a projection material. The substitution of non-conducting additives with the aforementioned projection material may be accomplished by co-sputtering methods employing targets for the GST and targets for the poorly conducting material. The projection material when integrated into the PCM as a substitute for the non-conducting material forms percolated conducting paths through the PCM elements from the bottom electrode to the top electrode which can provide reduced drift pathways.

When employing this lower drift phase change memory (PCM) composite matrix, the resetting stage closes off limits current through only the projection material, increasing resistance. It is noted that only the phase change material in the lower drift phase change memory (PCM) composite matrix is amorphized in reset. A reset pulse is achieved with phase change memory when the crystalline structure, i.e., state of crystalline structure, changes from crystalline to amorphous. This corresponds to logic ‘0’. In some embodiments, the current used for the reading the phase change memory (PCM) resistance avoids the high resistance, high drift reset phase change material volume, which reduces the effective drift measured of higher resistance (R) states.

The lower drift PCM composite matrix provided by the methods and structures of the present disclosure can provide a lower programming current to comparably non-composite and projection liner PCM by confining the phase change material volume, increasing its electrical resistance and improving Joule-Thomson heating internally. The lower drift PCM composite matrix provided by the methods and structure of the present disclosure can provide a slightly lower programming current or equal programming current to comparative PCM composites including non-conductive additives instead of the projection materials. That is unless projection material significantly reduces the overall thermal and electrical resistance of the PCM, which results in worse Joule-Thomson heating internally.

In one aspect, a phase change device is provided in which a low drift phase change composition matrix is provided of a phase change material with an additive that provides a projection material having a resistivity that is more than a crystalline phase of the phase change material and less than an amorphous phase of the phase change material. In one embodiment, the phase change material device includes a composite phase change material layer. The composite phase change material layer includes a mixture of a dispersed phase of a projection material of a first resistivity, and a matrix phase of a phase-change material of a second resistivity or third resistivity dependent on phase. The first resistivity of the projection material has a resistance that is greater than the second resistance for the phase change material and is less than the third resistance of the phase change material. The second resistivity corresponds to a crystalline phase of the phase change material. The third resistivity corresponds to an amorphous phase of the phase change material. The phase change material (PCM) further includes a first electrode and second electrode on opposing faces of the composite phase change material layer.

In some embodiments, the second resistivity corresponds to a crystalline phase of the phase change memory, and the third resistivity corresponds to an amorphous phase of the phase change material. The advantage here is that the first resistivity of the projection material is constant and does not transition like the phase change memory material. By providing a constant resistance path for the current between the electrodes, drift may be mitigated.

In some embodiments, the third resistivity of the amorphous phase is at least 20 times greater than that of the second resistivity of the crystalline phase. The electrical resistance of the percolated conducting path of the projection material may be greater than 5 times more than the electrical resistance of the percolated current path through the crystalline phase change material and has less electrical resistance than the resistance through the amorphous phase of the phase change material. In some embodiments, this is advantageous because the resistance of the percolated current path is selected to allow the phase change memory to function through its transitions between amorphous and crystalline material phases, yet provides a constant resistance path for the current between the electrodes so that drift may be mitigated.

In one embodiment, the phase change material device includes a matrix of phase-change material that includes alternating layers of the phase change material with layers of confinement material. In some embodiments, an advantage of this embodiment is that the different composition layers being alternated in the phase change material matrix can provide better internal thermal barriers, which can result in lower programming current.

In one embodiment, the phase change material device includes a matrix of the phase-change material that includes alternating layers of the phase change material and dispersed phase of a projection material with layers entirely of the phase change material. The layers that are composed entirely phase change material may have a different composition than the phase change material in the matrix phase. This embodiments may provide that there are no clear path between electrodes.

In another embodiment, a phase change memory device is provided that includes a composite phase change material layer comprising a mixture of a dispersed phase of a projection material of a first resistivity, and a matrix of a phase-change material of a second resistivity or third resistivity dependent on phase, wherein the first resistivity of the projection material has a resistance that is greater than the second resistance for the phase change material, and is less than the third resistance of the phase change material. The phase change memory device further includes a projection material layer in direct contact with a backside surface of the composite phase change material layer. A backside electrode is in direct contact with the projection material layer at the backside surface of the composite phase change material layer. A top electrode is present on an opposing face of the composite phase change material layer that is opposite the face of the composite phase change material layer that is in direct contact with the projection material layer. This embodiment includes an addition element of projection material. The projection material liner and the dispersed phase of a projection material provide at least two mechanisms for providing percolated conducting paths from the bottom electrode to the top electrode, which combined can further reduce drift effects.

In another aspect, a method for reducing drift effects in a phase change memory device is described that includes forming a composite phase change material layer comprising a mixture of a dispersed phase of a projection material of a first resistivity, and a matrix of a phase-change material of a second resistivity or third resistivity dependent on phase. The first resistivity of the projection material has a resistance that is greater than the second resistance for the phase change material, and is less than the third resistance of the phase change material. The method further includes forming a first electrode; and a second electrode on opposing faces of the composite phase change material layer, providing a current across the first and second electrode. The projection material forms a percolated conducting path from the first electrode to the second electrode through a phase change region of the composite phase change material layer. The phase change region is present at one of the first and second electrode.

In one embodiment, the projection material forms a percolated conducting path that has a constant resistance that reduces drift effects. In one embodiment, the step of forming of the composite phase change material layer includes a co-sputtering method that employs a first sputter target to provide the phase-change material of the matrix of the phase-change material, and a second sputter target to provide the dispersed phase of a projection material. The advantage of using two targets provides for control of the amount of dispersion in a manner that can provide the percolated conducting path that reduces drift effects.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a side cross-sectional view that illustrates a phase change memory device that includes a composite phase change material layer comprising a mixture of a dispersed phase of a projection material, and a matrix of a phase-change material of a second resistivity or third resistivity dependent on phase, in accordance with one embodiment of the present disclosure.

FIG. 2 is a side cross-sectional view that illustrates a phase change memory device that includes a composite phase change material layer comprising a mixture of a dispersed phase of a projection material, wherein the projection material forms a percolated conducting path from a first electrode to a second electrode, in accordance with one embodiment of the present disclosure.

FIG. 3 is a side cross-sectional view that illustrates a phase change memory device is provided that includes a composite phase change material layer comprising a mixture of a dispersed phase of a projection material, and a matrix of a phase-change material, wherein the phase change memory device further includes a projection material layer in direct contact with a backside surface of the composite phase change material layer, in accordance with one embodiment of the present disclosure.

FIG. 4 is a side cross-sectional view that illustrates a phase change memory device is provided that includes a composite phase change material layer comprising a mixture of a dispersed phase of a projection material, and a matrix of a phase-change material, wherein the composite phase change material layer further includes alternating layers of the phase change material and a confinement material, in accordance with one embodiment of the present disclosure.

FIG. 5 is a side cross-sectional view that illustrates a phase change memory device is provided that includes a composite phase change material layer comprising a mixture of a dispersed phase of a projection material, and a matrix of a phase-change material, wherein the composite phase change material layer further includes alternating layers of composite phase change material with projection material and layers solely (entirely) of the phase change material, or layers having phase change material of a different composition, in accordance with one embodiment of the present disclosure.

FIG. 6 is a side cross-sectional view of an initial structure for forming a phase change memory device, in accordance with one embodiment of the present disclosure.

FIG. 7 is a side cross-sectional view depicting one embodiment of forming a composite phase change material layer comprising a mixture of a dispersed phase of a projection material, and a matrix of a phase-change material on the first electrode depicted in FIG. 6.

FIG. 8 is a diagram of a sputtering apparatus including two sputtering targets for forming the composite phase change material layer, in accordance with one embodiment of the present disclosure.

FIG. 9 is a diagram of a sputtering apparatus including two sputtering targets for forming the composite phase change material layer further including a collimator.

FIG. 10 is a side cross-sectional view of forming a second electrode on the upper surface of the composite phase change material layer comprising a mixture of a dispersed phase of a projection material and a matrix of a phase-change material, in accordance with one embodiment of the present disclosure.

### DETAILED DESCRIPTION

Detailed embodiments of the claimed structures and methods are disclosed herein; however, it is to be understood that the disclosed embodiments are merely illustrative of the claimed structures and methods that may be embodied in various forms. In addition, each of the examples given in connection with the various embodiments is intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure. For purposes of the description hereinafter, the terms “upper”, “lower”, “right”, “left”, “vertical”, “horizontal”, “top”, “bottom”, and derivatives thereof shall relate to the embodiments of the disclosure, as it is oriented in the drawing figures. The terms “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

The development of phase change memory (PCM) faces several challenges. One of these is that the amorphous phase of phase-change materials exhibits undesirable attributes, such as low-frequency noise and drift. This drift causes resistance of the amorphous phase to increase in value over time. As a result, the read measurements for programmed cell states tend to vary with time. This complicates read out of the stored information, potentially even destroying the information if there is a large variability in the drift exhibited by different cell states so that the read measurement distributions for neighboring cell states interfere with one another. The larger the number of cell states, and so closer the initial spacing between readback resistance levels, the more susceptible cells are to this problem.

The methods and structures overcome the aforementioned problems with a lower drift phase change memory composite matrix. In some embodiments, the phase change memory (PCM) cell includes matrix of a phase-change material and a marginally conducting material, such as “bad” metals (TiNₓ, TaNₓ, WNₓ, WOₓ), doped semiconductors (doped Si, SiGe, SiC, Ge), small-bandgap semiconductors (Te, Se, etc.), semimetals (e.g., Bi, Sn), topological insulators (Bi₂Se₃, BiSb, BiSbTe), topological semimetals, van der Waal materials (WTe₂, MoTe₂, TiTe₂). The marginally conducting material forms percolated conducting paths from the bottom to the top electrode. The marginally conducting material that forms the percolated conductive paths may be referred to as a projection material or projection additive.

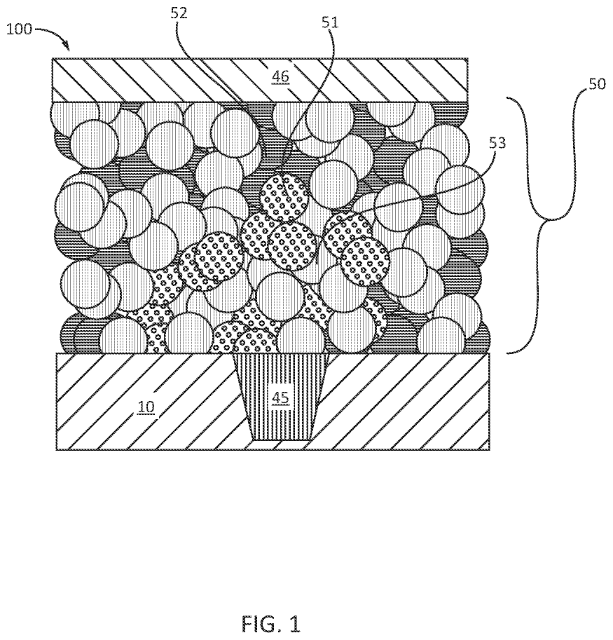

The methods and structures of the present disclosure are now discussed in greater detail with reference to FIGS. 1-10.

The term “phase change memory (PCM)” refers to a memory technology based on phase change materials, such as chalcogenide materials, that undergo a phase change via a heater (or current) and are read out as “0” or “1” based on their electrical resistivity, which changes in correspondence to whether the phase change material in the cell is in the crystalline or amorphous phase. The chalcogenide materials used in PCM comprise a large number of binary, ternary, and quaternary alloys of a number of metals and metalloids. Phase change memory (PCM) is a non-volatile solid-state memory technology that utilizes phase change materials having different electrical properties in their crystalline and amorphous phases. Specifically, the amorphous phase has a higher resistance than the crystalline phase. The term “amorphous phase” denotes a solid that lacks the long-range order that is characteristic of a crystal. A “crystalline phase” is a type of solid whose fundamental three-dimensional structure consists of a highly regular pattern of atoms or molecules, forming a crystal lattice.

PCM cells are often programmed using heat generated by an electrical current to control the state of phase change materials. Among the main key parameter of PCM technology are: RESET current and SET speed. RESET current affects the overall power consumption of the memory array, while SET speed controls the overall speed of the memory array.

The phase change memory (PCM) of the present disclosure incorporates the phase change material with a projection material in a composite. A “composite” is a material composed of two or more distinct phases, e.g., matrix phase and dispersed phase, and having bulk properties different from those of any of the constituents by themselves. As used herein, the term “matrix phase” denotes the phase of the composite, and contains the dispersed phase, and shares a load with it. In some embodiments, the matrix phase may be the majority component of the composite. As used herein, the term “dispersed phase” denotes a second phase (or phases) that is embedded in the matrix phase of the composite.

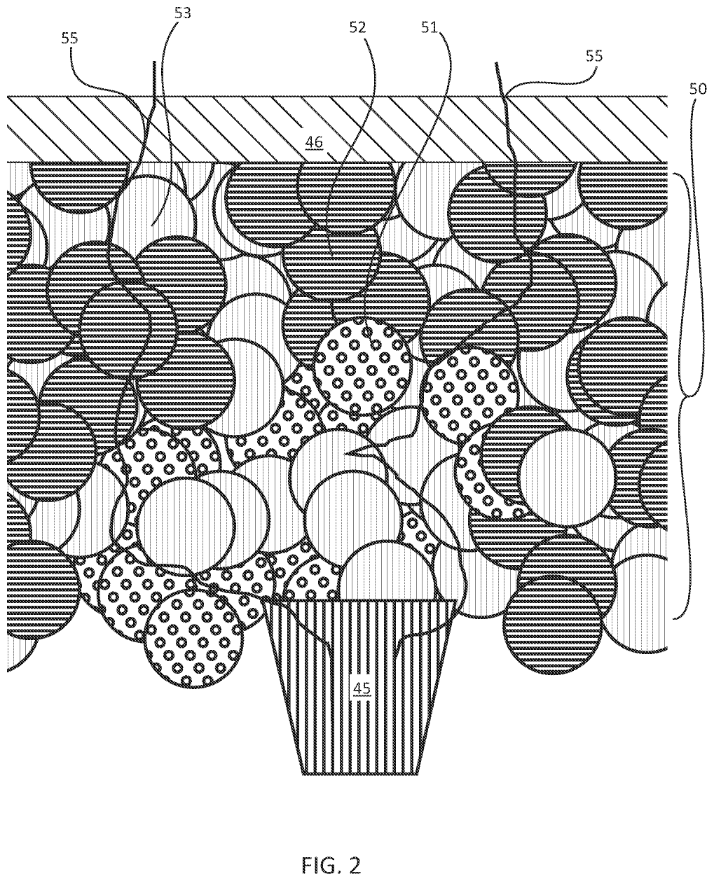

FIGS. 1 and 2 illustrates one embodiment of a phase change memory device 100 that includes a composite phase change material layer 50 including a mixture of a dispersed phase of a projection material 53 of a first resistivity, and a matrix of a phase-change material of a second resistivity or third resistivity dependent on phase. The phase change memory device 100 further includes a first electrode 45, and a second electrode 46 on opposing faces of the composite phase change material layer 50. The first electrode 45 in some instances may be referred to as a heater.

The composite phase change material layer 50 includes a phase change material of which a portion of the material comprising a high resistance amorphous phase and a portion of the material comprising a low resistance polycrystalline phase. The projection material 53 forms its own volume/phase including of one or more of metal nitrides, conductive oxides, metal antimonides, semiconductors, semimetals. The projection material 53 does not drift appreciably in resistance. The projection material forms a path (referred to as percolated conducting path 55) with an electrical resistance in between the resistance of the phase change memory layer when the phase change material is crystalline or amorphized. The high resistance amorphous phase change material 51 provides a high resistance conduction path 57 that drifts, but due to the higher resistance, conduction occurs along path 55 preferentially.

The composite phase change material layer 50 experiences a phase change between a crystalline stage and an amorphous stage. In some embodiments, the crystalline stage phase change material 52 has the lesser resistance, while the amorphous stage phase change material 51 has the greater resistance. In some embodiments, the first resistivity of the projection material 53 has a resistance that is greater than the second resistivity for the phase change material (crystalline stage phase change material 52) and is less than the third resistivity of the phase change material (amorphous stage phase change material 51). In some embodiments, the third resistivity of the amorphous phase is at least 20 times greater than that of the second resistivity of the crystalline phase for the phase change material, e.g., GST, that provides the matrix for the composite phase change material layer 50.

Phase change based memory materials, like chalcogenide based materials and similar materials, can be caused to change between an amorphous phase and a crystalline phase by application of electrical current at levels suitable for implementation in integrated circuits. The amorphous phase is characterized by higher electrical resistivity than the crystalline phase, which can be readily read to indicate DATA. These properties are applicable for use as programmable resistive materials to form non-volatile memory circuits, which can be read and written with random access.

The change from the amorphous phase to the crystalline phase is generally a lower current operation. The change from crystalline to amorphous, referred to as RESET herein, is generally a higher current operation, which includes a short high current density pulse to melt or breakdown the crystalline structure, after which the phase change material cools quickly, quenching the phase change process and allowing at least a portion of the phase change material to stabilize in the amorphous phase.

Referring to FIGS. 1 and 2, the matrix of the phase change material, which provides the crystalline stage phase change material 52 and the amorphous stage phase change material 51 in the active region of the composite phase change material layer 50 may be a germanium (Ge), antimony (Sb), and tellurium (Te) (GST) composition. For example, the matrix phase change material of memory device may comprises Ge₂Sb₂Te₅. Other phase change materials may be used, including Ge(x)Sb(2y)Te(x+3y), where x and y are integers (including 0). Other basis phase change materials other than GeSbTe-based materials can also be used, including GaSbTe system, which can be described as Ga(x)Sb(x+2y)Te(3y), and x, y are integers. Alternatively, the basis phase change material can be selected from an Ag(x)In(y)Sb₂Te₃ system, where x, y decimal numbers that can be below 1. In some embodiments, matrix of the phase material may include additional additives to the base of Ge₂Sb₂Te₅. However, many other phase change based memory materials have been contemplated for the matrix of the composite phase change material layer 50, including alloys of: Ga/Sb, In/Sb, In/Se, Sb/Te, Ge/Te, Ge/Sb/Te, In/Sb/Te, Ga/Se/Te, Sn/Sb/Te, In/Sb/Ge, Ag/In/Sb/Te, Ge/Sn/Sb/Te, Ge/Sb/Se/Te and Te/Ge/Sb/S. In one embodiment, the matrix of the composite phase change material layer 50 has an average concentration of Te below 70%, typically below about 60%, and ranged in general from as low as about 23% up to about 58% Te. Concentrations of Ge can be above about 5% and can range from a low of about 8% to about 30% average in the material. In some examples, the germanium (Ge) content is below 50%. The remainder of the principal constituent elements in this composition was Sb. These percentages are atomic percentages that total 100% of the atoms of the constituent elements.

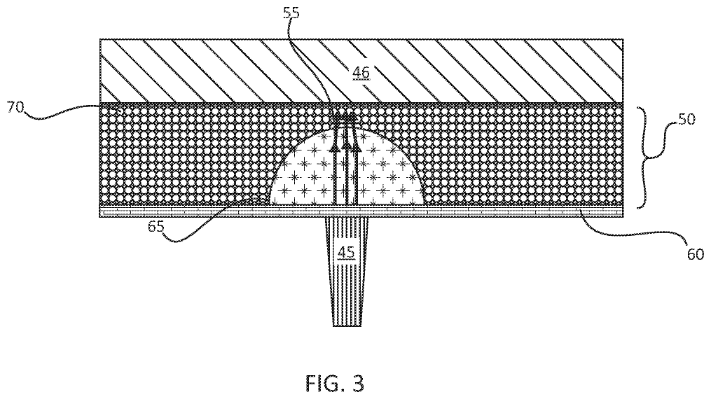

The projection material 53 forms a percolated conducting path 55 from the first electrode 45 to the second electrode 46, as depicted in FIG. 2. The percolated conducting path 55 may extend through the amorphous phase of the matrix phase change material that may be present in the active region of the phase change memory (PCM) device 100, and provides a constant current electrical pathway between the first and second electrodes 45, 46 that can reduce drift. FIG. 2 illustrates a phase change memory device 100 that includes a composite phase change material layer 50 comprising a mixture of a dispersed phase of a projection material 53, wherein the projection material 53 forms a percolated conducting path 55 from a first electrode 45 to a second electrode 46. By percolated conducting path 55, it is meant that if the current can not pass through an amorphous region of the phase change material, the current can still travel along the percolated conducting path 55 of projection material 53 through the composition phase change material 50 between the electrodes 45, 46. It is noted that the matrix of the phase change material has a resistance that changes depending upon the degree of amorphous character. This occurs in the active region of the of the phase change memory (PCM) device 100 that is in direct contact with one of the first and second electrodes, which experiences phase changes as part of the operation of the memory device for storing DATA and RESET operations. Prior to the structures and methods of the present disclosure, the variations in resistance between the different crystalline states is a mechanism by which drift effects can prior to required additional hardware and/or programming to mitigate. However, the programmability of the conductance was subject to drift, which previously hindered the ability to program analog states for the phase change memory. The percolated conducting path 55 of the projection material 53 has a constant resistance between the resistance of the amorphous phase of the phase change material and the crystalline phase of the phase change material, which has surprisingly and unexpectedly been determined to reduce drift effects. The constant resistance of the percolated conducting path 55 is opposite the variability of the crystalline stage phase change material 52 and the amorphous stage phase change material 51 in the active region of the composite phase change material layer 50 that is directly on the first electrode 45. The active region of the composite phase change material layer is depicted in FIGS. 3-6, as identified by reference number 65.

In some embodiments, the projection material 53 is a metal nitride, metal oxide, doped semiconductor, small bandgap semiconductor, topological insulator, topological semimetals, a Van der Waal material or a combination thereof. The electrical resistance of the percolated conducting path 55 of the projection material 53 has greater than 5 times more electrical resistance than percolated current path 55 through the crystalline phase change material 52 and has less electrical resistance than the resistance through the amorphous phase of the phase change material 51.

In some embodiments, when the projection material 53 is a metal nitride, the metal nitride may be selected from titanium nitride (TiNₓ), tantalum nitride (TaNx̅), tungsten nitride (WNx), aluminum nitride (AlNx) and combinations thereof. In some embodiments, when the projection material 53 is a doped semiconductor, the doped semiconductor may be selected from doped Si, doped SiGe, doped silicon carbide (SiC), doped germanium (Ge), and combinations thereof.

In some embodiments, the projection material 53 is a small bandgap semiconductor. Narrow (small)-gap semiconductors are semiconducting materials with a band gap that is comparatively small compared to that of silicon, i.e., smaller than 1.11 eV at room temperature. In some embodiments, when the projection material 53 is a small bandgap semiconductor, the composition can be selected from tin telluride, titanium telluride, germanium, selenium, InSb, InAs, GaSb, AlSb and combinations thereof.

In some embodiments, the projection material 53 may be a semimetal. A semimetal is a material with a very small overlap between the bottom of the conduction band and the top of the valence band. In some examples, when the projection material 53 is a semimetal, it may be selected from bismuth, tin (Sn), mercury, graphite and combinations thereof.

In other examples, the projection material 53 may be a topological insulator. Topological insulators are quantum matter that features a bulk gap and an odd number of relativistic Dirac fermions on their surfaces. While their bulk is insulating, the surfaces can conduct electric current with a well-defined spin texture. In some examples, the topological insulator for the projection material 53 may be Bi₂Se₃, BiSb, BiSbTe and combinations thereof.

In further examples, the projection material 53 may be a topological semiconductor. Topological semiconductors are quantum matter that features a bulk gap and an odd number of relativistic Dirac fermions on their surfaces. While their bulk is insulating, the surfaces can conduct electric current with a well-defined spin texture. In some examples, the topological insulator for the projection material 53 may be Bi₂Se₃, BiSb, BiSbTe and combinations thereof.

In some examples, the projection material 53 may be a topological semiconductor. Topological semimetals define a class of gapless electronic phases exhibiting topologically stable crossings of energy bands. Topological semimetals, such as Dirac, Weyl, or line-node semimetals, are gapless states of matter characterized by their nodal band structures and surface states. Some examples of suitable topological semiconductors may include graphene, Weyl semimetals like TaAs and WTe₂, and Dirac semimetals like Na₃Bi or Cd₃As.

In a further example, the projection material comprises a Van der Waal material selected from the group consisting of WTe₂, MoTe₂, TiTe₂ and combinations thereof.

In some further embodiments, the composite layer may further include an additional dispersed phase of non-conducting additive, e.g., dielectric. For example, the non-conducting additive may be selected from the group consisting of Al₂O₃, Si₃N₄, SiO₂, SiO, TiO₂, HfO₂, and combinations thereof.

It is noted that the above examples are provided for illustrative purposes only, and it is not intended that the present disclosure be limited to only those examples. Other materials suitable for providing conductive pathways between the electrodes, and having resistance between the resistance of the amorphous and crystalline states of the phase change material of the matrix may also be suitable for the projection material 53. For example, the electrical resistance (i.e., first resistivity) of the percolated conducting path 55 of the projection material 53 has greater than 5 times more electrical resistance than percolated current path 55 through the crystalline phase change material of the matrix, and has less electrical resistance than the resistance through the amorphous phase of the phase change material of the matrix. The resistivity of the amorphous phase (i.e., third resistivity) of the phase change material for the matrix of the composite phase change material layer 50 is at least 20 times greater than that of the resistivity (i.e., second resistivity) of the crystalline phase of the phase change material for the matrix of the composite phase change material layer 50.

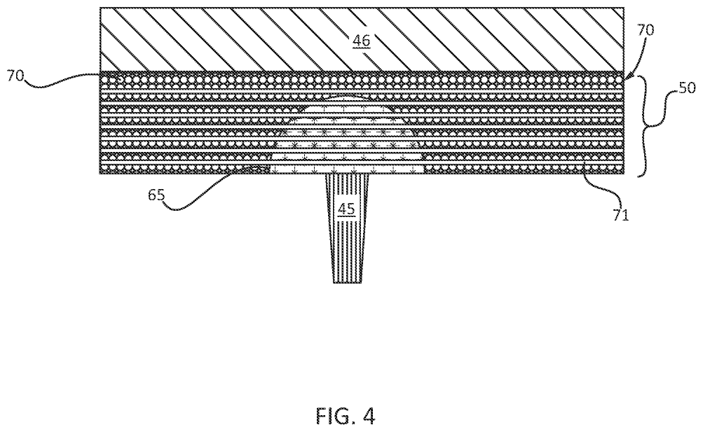

It is noted that the structures and methods configurations of the present disclosure are not limited to only the embodiments depicted in FIGS. 1-2. For example, FIG. 3 illustrate one embodiment of a memory device including a composite phase change material layer 50 having a mixture of a dispersed phase of a projection material 53 in combination with a further layer of projection material similar to projection liner that is positioned between the composite phase change material layer 50 and the first electrode 45. FIGS. 4 and 5 illustrate another embodiment a phase change heterostructured memory layer 50 comprised of alternating composite phase change memory layers 70 comprising a phase change material and projection material and confinement layers 71, 72.

FIG. 3 is a side cross-sectional view that illustrates a phase change memory device 100 is provided that includes a composite phase change material layer 50 comprising a mixture of a dispersed phase of a projection material 53, and a matrix of a phase-change material 70. More particularly, in one embodiment, the phase change memory device 100 includes a composite phase change material layer 70 comprising a mixture of a dispersed phase of a projection material of a first resistivity, and a matrix of a phase-change material of a second resistivity or third resistivity dependent on phase, wherein the first resistivity of the projection material has a resistance that is greater than the second resistance for the phase change material, and is less than the third resistance of the phase change material. The phase change memory device 100 further includes a projection material layer 60 in direct contact with a backside surface of the composite phase change material layer 70. In some embodiments, a backside electrode 45 in direct contact with the projection material layer 60 at the backside surface of the composite phase change material layer 70. The phase change memory device 100 further includes a top electrode 46 on an opposing face of the composite phase change material layer 70 that is opposite the face of the composite phase change material layer 70 that is in direct contact with the projection material layer 60.

In some embodiments, the matrix of the phase change material 70 includes a portion of the material comprising a high resistance amorphous phase and a portion of the material comprising a low resistance polycrystalline phase. The matrix of the phase change material is similar to the phase change material that is described above with reference to FIGS. 1 and 2 that includes phase changes resulting in a crystalline stage phase change material 52 and an amorphous stage phase change material 51 in the active region of the composite phase change material layer 50.

Referring to FIG. 3, the dispersed phase of a projection material 53 forms its own volume/phase comprised of one or more of metal nitrides, conductive oxides, metal antimonides, semiconductors, semimetals. The above description for the projection material 53 depicted in FIGS. 1 and 2 is suitable for the description of the projection material 53 that is depicted in FIG. 3. The projection material 53 that is present in the matrix of the phase change material 70 forms a path with an electrical resistance in between the resistance of the phase change memory material when the phase change material is crystalline or amorphized. The path may be referred to as a percolated conducting path 55. The projection material 53 in the percolated projection path 55 does not drift appreciably in resistance.

Still referring to FIG. 3, the device further includes a projection material layer 60 in direct contact with a backside surface of the composite phase change material layer 70. The projection material layer 60 is present between the composite phase change material layer 70 and the first electrode 45. The projection material layer 60 may be composed of a same material composition as the projection material 53 that is described above with reference to FIGS. 1 and 2. The projection material liner 60 and the dispersed phase of a projection material 53 provide at least two mechanisms for providing percolated conducting paths from the bottom electrode 45 to the top electrode 46, which combined can further reduce drift effects.

FIG. 4 illustrates another embodiment of a phase change memory device 100 that includes a composite phase change material layer 50 comprising a mixture of a dispersed phase of a projection material, and a matrix of a phase-change material, wherein the composite phase change material layer further includes alternating layers of the composite phase change material 70 and conductive material 71. The alternating structure may be referred to as a heterostructure. In some embodiments, an advantage of this embodiment is that the different composition layers being alternated in the phase change material matrix 70 and the conductive material layer 71 can provide better internal thermal barriers, which can result in lower programming current. The layers of the composite phase change material 70 have a composition of phase change material 51, 52 and projection material 53 as described above with reference to FIGS. 1 and 2. The conductive material layer 71 may also be referred to as a confinement layer. The confinement layers can form Van der Waal gaps with the phase change material (PCM). The conductive material layer 71 may be composed of Sb₂Te₃ or TiTe₂. It is noted that the above compositions are provided for illustrative purposes only. For example, the confinement layers (also referred to as conductive material layers 71) may also be composed of materials having a comparable resistance (˜ 1/10th to 10× resistance) to the phase change material crystalline resistance comprised of one or more of metal nitrides, conductive oxides, metal antimonides, semiconductors, semimetals and combinations thereof.

FIG. 5 illustrates another embodiment of a phase change memory device 100 that includes a composite phase change material layer comprising a mixture of a dispersed phase of a projection material, and a matrix of a phase-change material. In the embodiment depicted in FIG. 5 the composite phase change material layer 50 further includes alternating layers of composite phase change material 70 and layers solely of the phase change material 71. The composite phase change material 70 includes the projection material 53 that is described above with reference to FIGS. 1 and 2. The composite phase change material 70 employs the phase change material as the matrix of the composite, and the projection material is the dispersed phase. The layers that are solely composed of the phase change material 71 do not include the projection material. The composition of the phase change material in the layers identified by reference number 71 may be the same composition as in the composite phase change material 70. In other embodiments, the composition of the phase change material in the layers identified by reference number 71 may be different from composition that is in the composite phase change material 70. It is noted that the compositions for the phase change materials described above with reference to FIGS. 1 and 2 can provide the composition for the phase change materials for the embodiments depicted in FIG. 5. The dispersed phase of the projection material forms a percolated conducting path from the first electrode 45 to the second electrode 46. The percolated conducting path 55 may extend through the amorphous phase of the matrix phase change material that may be present in the active region of the phase change memory (PCM) device 100, and provides a constant current electrical pathway between the first and second electrodes 45, 46 that can reduce drift.

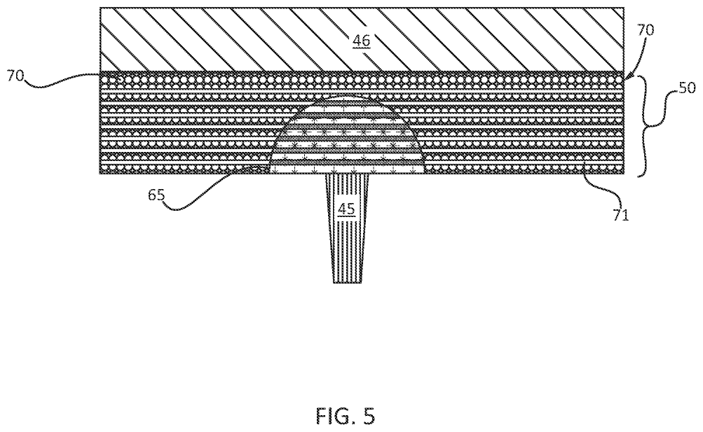

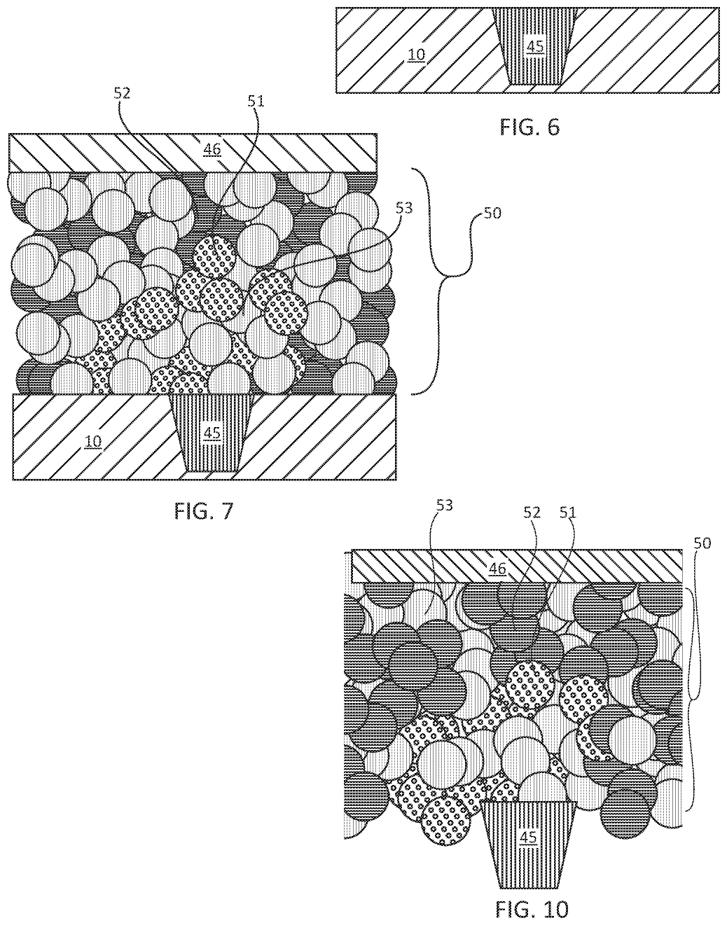

In another aspect, a method for reducing drift effects in a phase change memory device 100 is described that includes forming a composite phase change material layer 50 comprising a mixture of a dispersed phase of a projection material 53 of a first resistivity, and a matrix of a phase-change material 51, 52 of a second resistivity or third resistivity dependent on phase. The first resistivity of the projection material has a resistance that is greater than the second resistance for the phase change material, and is less than the third resistance of the phase change material. The method further includes forming a first electrode 45, and a second electrode 46 on opposing faces of the composite phase change material layer 50, and providing a current across the first and second electrode 45, 46. The projection material 53 forms a percolated conducting path 55 from the first electrode 45 to the second electrode 46 through a phase change region of the composite phase change material layer 50. The phase change region 65 is present at one of the first and second electrode. In one embodiment, the projection material forms a percolated conducting path 55 that has a constant resistance that reduces drift effects. The method is further described with reference to FIGS. 6-10.

FIG. 6 depicts one embodiment of an initial structure for forming a phase change memory device 100. In one embodiment, the initial structure includes a bottom electrode 45 embedded in an insulating substrate 10 in accordance with an embodiment of the present application. Although a single bottom electrode 45 is described and illustrated, a plurality of bottom electrodes may be formed into the insulating substrate 10. In some embodiments, the bottom electrode 45 only partially extends through the insulating substrate 10, as shown. In other embodiments of the present application, the bottom electrode 45 extends through the entirety of the insulating substrate 10.

The insulating substrate 10 may comprise any dielectric material including for example, silicon dioxide, silicon nitride, silicon oxynitride, silsesquioxanes, or C doped oxides (i.e., organosilicates) that include atoms of Si, C and H. The insulating substrate 10 can be formed utilizing a deposition process including, for example, chemical vapor deposition (CVD), plasma enhanced chemical vapor deposition (PECVD), spin-on coating, evaporation or chemical solution deposition. The insulating substrate 10 may be formed on a base substrate not shown. The base substrate may include a semiconductor material, an insulator material, and/or conductive material.

In some embodiments, an opening is then formed into the insulating layer 10 and then bottom electrode 45 is formed within the opening. The bottom electrode 45 may also be referred to as a first electrode. The opening can be formed utilizing lithography and etching. After forming the opening within the insulating substrate 10, the bottom electrode 45 is formed by deposition of a conductive metallic material into the opening. The conductive metallic material that provides the bottom electrode 45 may include, but is not limited to, titanium nitride (TiN), tungsten (W), silver (Ag), gold (Au), aluminum (Al) or multilayered stacks thereof. The conductive metallic material may be formed by a deposition process such as, for example, CVD, PECVD, physical vapor deposition (PVD), sputtering, atomic layer deposition (ALD) or plating. A planarization process or an etch back process may follow the deposition of the conductive metallic material that provides the bottom electrode 45. As is shown, the bottom electrode 45 has a topmost surface that is coplanar with a topmost surface of the insulating substrate 10. The exemplary semiconductor structure shown in FIG. 6 may also be formed by first providing the bottom electrode 45 on a surface of a base substrate (not shown) by deposition of a conductive metallic material, followed by patterning the deposited conductive metallic material by lithography and etching. The insulating substrate 10 may then be formed by deposition of a dielectric material, followed by planarization or an etch back process.

FIG. 7 depicts one embodiment of forming a composite phase change material layer 50 comprising a mixture of a dispersed phase of a projection material 53, and a matrix of a phase-change material 52 on the first electrode (also referred to as bottom electrode) 45 depicted in FIG. 6.

In one embodiment, the step of forming of the composite phase change material layer 50 includes a co-sputtering method that employs a first sputter target to provide the phase-change material of the matrix of the phase-change material 51, 52, and a second sputter target to provide the dispersed phase of a projection material 53. The advantage of using two targets provides for control of the amount of dispersion in a manner that can provide the percolated conducting path 55 that reduces drift effects. For example, the dispersed phase of projection material 53 may be present in the matrix of the phase change material in a concentration ranging from 5% to 40%.

As used herein, “sputtering” means a method of depositing a film of material on a semiconductor surface. A target of the desired material, i.e., source, is bombarded with particles, e.g., ions, which knock atoms from the target, and the dislodged target material deposits on the deposition surface. Examples of sputtering techniques suitable for depositing the metallic adhesion layer 16, but are not limited too, DC diode sputtering (“also referred to as DC sputtering”), radio frequency (RF) sputtering, magnetron sputtering, and ionized metal plasma (IMP) sputtering. Co-sputtering uses two sputtering targets.

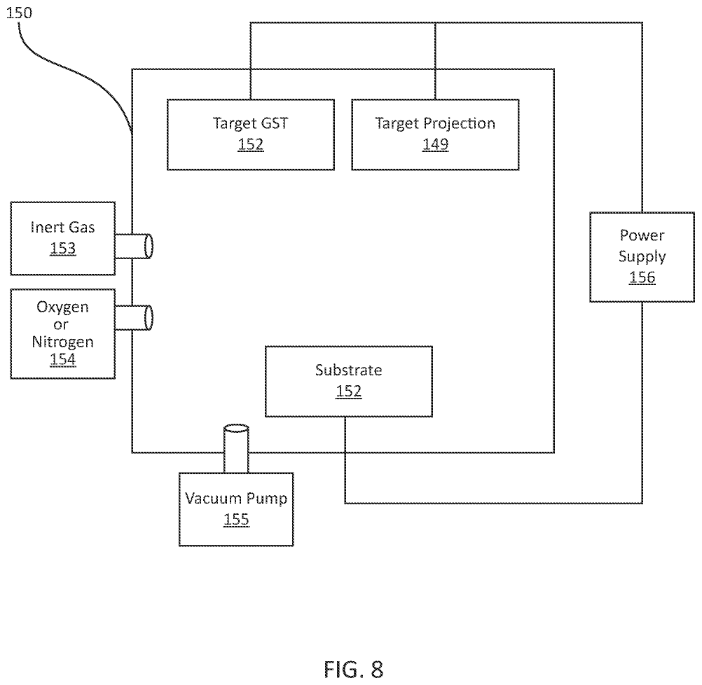

FIG. 8 is a diagram of a sputtering apparatus including two sputtering targets 149, 151 for forming the composite phase change material layer 50 including the dispersed phase of the projection material 53. The sputtering system includes a chamber 150 in which the sputter targets 149, 151 and a substrate 152 are mounted. The sputter targets 149, 151 and substrate 152 are coupled to a power supply and controller 156 used to apply bias voltages during the sputtering process. Bias voltages applied can be DC, pulsed DC, radio frequency, and combinations thereof, and turned on and off and modulated by the controller, as suits a particular sputtering process. The sputter chamber 150 is equipped with a vacuum pump 155 or other means for evacuating the chamber and removing exhaust gases. Also, the chamber is configured with a source 153 of inert gas, such as argon and a source 154 of the reaction gas, such as oxygen or nitrogen in the examples described here. The system has the ability to dynamically control the flow of gases from the sources 153, 154 in order to have an effect on the composition of the layer being formed in the sputtering process. The sputter target identified by reference number 151 comprises the composition of the phase change material, and acts as a source of material used to form the matrix of the composite phase change material layer 50 on a substrate 152. The substrate includes the first electrode 45 (also referred to as bottom electrode 45). The sputter target identified by reference number 149 comprises the composition of the projection material 53, and acts as a source of material to form the dispersed phase within the composite phase change material layer 50.

It will be appreciated that this is a simplified diagram sufficient for purposes of description herein.

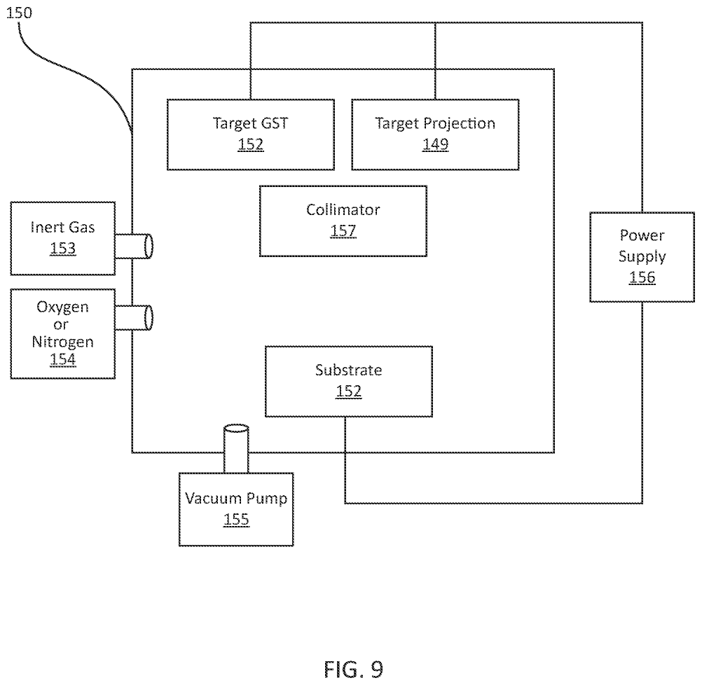

FIG. 9 is a simplified diagram of an alternative sputtering system, which can also be used with a composite target as described herein. FIG. 9 differs from FIG. 8, in that a collimator 157 is placed between the targets 149, 151 and the substrate 152. The collimator 157 can be used when sputtering a substrate that includes high aspect ratio features, to improve the uniformity of coverage over the high aspect ratio features. Some sputtering systems have the ability to move a collimator into and out of the sputtering chamber as needed.

In some embodiments, the composite phase change material layer 50 is deposited using one of the sputtering apparatus that are depicted in FIGS. 8 and 9. In some embodiments, the phase change material of the phase change material layer 50 may be deposited in a crystalline phase. However, this is only one example, and is not necessary in some embodiments.

FIG. 10 depicts forming a second electrode 46 on the upper surface of the composite phase change material layer 50 comprising a mixture of a dispersed phase of a projection material and a matrix of a phase-change material. The second electrode 46 (also referred to as top electrode) may comprise one of the conductive metallic materials mentioned above in providing the first electrode 45 (bottom electrode). In some embodiments, the second electrode 46 and the first electrode 45 comprise a same conductive metallic material. In other embodiments, the second electrode 46 and the bottom electrode 45 comprise a different conductive metallic material. The second electrode 46 may be formed using plating, electroplating, sputtering or other deposition methods including forms of physical vapor deposition, and chemical vapor deposition, etc.

The methods further include applying a current across the first and second electrode 45, 46, wherein the projection material 53 forms a percolated conducting path 55 from the first electrode 45 to the second electrode 46 through a phase change region 65 of the composite phase change material layer 50 at one of the first and second electrode 45, 46. The active region (also referred to as phase change region 65) includes a region of the composite layer 50 that experiences a phase change between amorphized 51 and reference crystalline 52 phases of the phase change material. The amorphous region is highly resistive. The degree of amorphous crystalline character impacts the resistivity of the phase. This results in variability that causes drift. The projection material 53 forms a percolated conducting path that has a constant resistance that reduces drift effects.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as readily apparent by one of ordinary skill in this and related arts, for as many items listed.

Having described preferred embodiments of a system and method (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A phase change memory device comprising:
a composite phase change material layer comprising a mixture of a dispersed phase of a projection material of a first resistivity, and a matrix of a phase-change material of a second resistivity or third resistivity dependent on phase, wherein the first resistivity of the projection material has a resistance that is greater than the second resistance for the phase change material, and is less than the third resistance of the phase change material;
a first electrode; and
a second electrode on opposing faces of the composite phase change material layer, wherein the projection material forms a percolated conducting path from the first electrode to the second electrode.

2. The phase change memory device of claim 1, wherein the second resistivity corresponds to a crystalline phase of the phase change memory, and the third resistivity corresponds to an amorphous phase of the phase change material.

3. The phase change memory device of claim 1, wherein the projection material comprises a metal nitride, metal oxide, doped semiconductor, small bandgap semiconductor, topological insulator, topological semimetals, a Van der Waal material or a combination thereof.

4. The phase change memory device of claim 1, wherein the projection material comprises a metal nitride selected from the group consisting of titanium nitride (TiNₓ), tantalum nitride (TaNₓ), tungsten nitride (WNₓ), aluminum nitride (AlNₓ) and combinations thereof.

5. The phase change memory device of claim 1, wherein the projection material comprises a doped semiconductor selected from the group consisting of doped Si, doped SiGe, doped silicon carbide (SiC), doped germanium (Ge), and combinations thereof.

6. The phase change memory device of claim 1, wherein the projection material is a small bandgap semiconductor selected from the group consisting of tin telluride, titanium telluride, gallium germanium, selenium, InSb, InAs, GaSb, AlSb and combinations thereof.

7. The phase change memory device of claim 1, wherein the projection material is a semimetal selected from the group consisting of bismuth, tin (Sn), mercury telluride, graphite and combinations thereof.

8. The phase change memory device of claim 1, wherein the projection material comprises a topological material selected from the group consisting of Bi₂Se₃, BiSb, BiSbTe, graphene, TaAs, WTe₂, Na₃Bi, Cd₃As₂ and combinations thereof.

9. The phase change memory device of claim 1, wherein the projection material comprises a Van der Waal material selected from the group consisting of WTe₂, MoTe₂, TiTe₂ and combinations thereof.

10. The phase change memory device of claim 2, wherein the third resistivity of the amorphous phase is at least 20 times greater than that of the second resistivity of the crystalline phase.

11. The phase change memory device of claim 10, wherein the electrical resistance of the percolated conducting path of the projection material has greater than 5 times more electrical resistance than percolated current path through the crystalline phase change material and has less electrical resistance than the resistance through the amorphous phase change material of the phase change material.

12. The phase change memory device of claim 1, wherein the matrix of the phase-change material includes alternating layers of the phase change material with layers of conductive material.

13. The phase change memory device of claim 1, wherein the matrix of the phase-change material includes alternating layers of the phase change material and dispersed phase of a projection material with layers entirely of the phase change material.

14. The phase change memory device of claim 1, wherein the composition phase change material layer further comprises a non-conducting additive selected from the group consisting of Al₂O₃, Si₃N₄, SiO₂, SiO, TiO₂, HfO₂, and combinations thereof.

15. A phase change memory device comprising:
a composite phase change material layer comprising a mixture of a dispersed phase of a projection material of a first resistivity, and a matrix of a phase-change material of a second resistivity or third resistivity dependent on phase, wherein the first resistivity of the projection material has a resistance that is greater than the second resistance for the phase change material, and is less than the third resistance of the phase change material;
a projection material layer in direct contact with a backside surface of the composite phase change material layer;
a backside electrode in direct contact with the projection material layer at the backside surface of the composite phase change material layer; and
a top electrode on an opposing face of the composite phase change material layer that is opposite the face of the composite phase change material layer that is in direct contact with the projection material layer, wherein the projection material forms a percolated conducting path from the first electrode to the second electrode.

16. A method for reducing drift effects in a phase change memory device comprising:
forming a composite phase change material layer comprising a mixture of a dispersed phase of a projection material of a first resistivity, and a matrix of a phase-change material of a second resistivity or third resistivity dependent on phase, wherein the first resistivity of the projection material has a resistance that is greater than the second resistance for the phase change material, and is less than the third resistance of the phase change material;
forming a first electrode and a second electrode on opposing faces of the composite phase change material layer; and
applying a current across the first and second electrode, wherein the projection material forms a percolated conducting path from the first electrode to the second electrode through a phase change region of the composite phase change material layer at one of the first and second electrode, wherein the projection material forms a percolated conducting path from the first electrode to the second electrode.

17. The method of claim 16, wherein the forming of the composite phase change material layer comprises a co-sputtering method that employs a first sputter target to provide the phase-change material of the matrix of the phase-change material, and a second sputter target to provide the dispersed phase of a projection material.

18. The method of claim 16, wherein the second resistivity corresponds to a crystalline phase of the phase change memory, and the third resistivity corresponds to an amorphous phase of the phase change material.

19. The method of claim 16, wherein the projection material comprises a metal nitride, metal oxide, doped semiconductor, small bandgap semiconductor, topological insulator, topological semimetals, a Van der Waal material or a combination thereof.

20. The method of claim 18, wherein the third resistivity of the amorphous phase is at least 20 times greater than that of the second resistivity of the crystalline phase.
